(19) United States
(12) Patent Application Publication
(10) Pub. No.: US 2020/0040457 A1
(43) Pub. Date: Feb. 6, 2020

(54) WIRING CORRECTING DEVICE AND WIRING CORRECTING METHOD

(71) Applicant: V TECHNOLOGY CO., LTD., Yokohama-shi, Kanagawa (JP)

(72) Inventors: Yoshikazu SUZUKI, Yokohama-shi, Kanagawa (JP); Yosuke KUSUMI, Yokohama-shi, Kanagawa (JP)

(73) Assignee: V TECHNOLOGY CO., LTD., Yokohama-shi, Kanagawa (JP)

(21) Appl. No.: 16/476,389

(22) PCT Filed: Dec. 22, 2017
(86) PCT No.: PCT/JP2017/046246

§ 371 Date: Jul. 8, 2019

(30) Foreign Application Priority Data
Jan. 11, 2017 (JP) 2017-002541

(51) Int. Cl. C23C 16/48; C23C 16/16; H01L 21/768

(52) U.S. Cl. CPC C23C 16/483; H01L 21/76894; C23C 16/16

(57) ABSTRACT

A wiring correcting device is configured for irradiation of a beam of CVD-addressing laser light oscillated by a CVD-addressing laser oscillator to cause a photo-degradation of a CVD-addressing raw material gas to develop on a laser-irradiated surface of a correction-addressing substrate, thereby forming a length of correction-addressing metal wiring on the laser-irradiated surface, and provided with a modification-addressing laser oscillator, which is configured to oscillate a beam of modification-addressing laser light different in wavelength from the beam of CVD-addressing laser light, and adapted for melting agglomerates of a correction-addressing metal to be solidified.

### FIELD OF ART

This invention relates to wiring correcting devices and wiring correcting methods, and more specifically, to techniques of using a laser CVD (Chemical Vapor Deposition) method to have pieces of correction-addressing metal wiring formed on a substrate surface.

### BACKGROUND ART

FPDs (Flat Panel Displays), such as liquid crystal displays and organic EL (Electro Luminescence) displays, include a TFT (Thin Film Transistor) substrate having, among others, for instance, many thin film transistors and many minute wiring patterns or such formed thereon. There are repairing treatments to be implemented in cases defects are found in wiring patterns on the TFT substrate. As one of such repairing treatments, there is known a treatment using a disconnection correcting method disclosed in Patent Document 1 below, for instance. The disconnection correcting method includes a laser CVD method to be employed at a location involving an occurrence of disconnection, to have a conductive film selectively formed therein for a connection of wiring.

### TECHNICAL DOCUMENTS IN THE PAST

### Patent Documents

Patent Document 1: JP 2006-317726 A

### SUMMARY OF INVENTION

### Problem to be Solved by Invention

Recent years have observed advancements in image definition enhancement as well as screen size enlargement of FPDs. FPDs had, among others, sizes of their pixels as well as dimensions in width of their wirings further miniaturized along with enhancements in definition of images. FPDs had their numbers of pixels increased along with enlargements in size of screen. Due to such increases in pixel number or like factors, FPDs had their refresh rates heightened in frequency. Frequency-heightened refresh rates might have increased FPD drive currents. For instance, even in organic EL displays which had their drive systems configured as current drive types, their TFT drive currents might have been increased. Along with such increases in drive currents, there has been an accompanying need for wirings on TFT substrates to have reduced resistances. Likewise, there have been needs for reduced resistances also in pieces of correction-addressing metal wirings to be formed at locations of wirings to be corrected. The laser CVD method employed above gave pieces of wirings formed as sets of particulate agglomerates of a metal. It therefore was difficult to approximate them to low resistance values the metal inherently could have.

This invention has been devised in view of the problem noted above, and it is an object thereof to provide a wiring correcting device and a wiring correcting method adapted to implement reduced resistances of pieces of correction-addressing metal wirings formed by employing a laser CVD method.

### Solution to the Problem

As a solution to the problem described to attain the object, according to aspects of this invention, there is given a wiring correcting device configured to have a beam of CVD-addressing laser light oscillated at a CVD-addressing laser oscillator and irradiated on a correction-addressing substrate exposed to a CVD-addressing raw material gas at a side thereof, causing a photo-degradation of the CVD-addressing raw material gas to develop on a laser-irradiated surface of the correction-addressing substrate, having agglomerates of a correction-addressing metal selectively deposited on the laser-irradiated surface, to form a length of correction-addressing metal wiring thereon, wherein the wiring correcting device comprises a modification-addressing laser oscillator, and the modification-addressing laser oscillator is configured to oscillate a beam of modification-addressing laser light having a different wavelength relative to the beam of CVD-addressing laser light, and adapted to melt agglomerates of the correction-addressing metal.

According to one of the aspects, the wiring correcting device may preferably comprise an optical system operable to have the beam of CVD-addressing laser light and the beam of modification-addressing laser light irradiated at a region on the correction-addressing substrate.

According to one of the aspects, the wiring correcting device may preferably be configured to be set to have the beam of CVD-addressing laser light and the beam of modification-addressing laser light oscillated concurrently.

According to one of the aspects, the wiring correcting device may preferably be configured to be set to irradiate the beam of CVD-addressing laser light to form the length of correction-addressing metal wiring, before irradiating the beam of modification-addressing laser light on the length of correction-addressing metal wiring.

According to one of the aspects, the beam of CVD-addressing laser light may preferably comprise ultraviolet laser light, and the beam of modification-addressing laser light may preferably comprise pulse-oscillated infrared laser light.

According to one of the aspects, the wiring correcting device may preferably comprise a 2-wavelength outputting laser oscillator serving as a combination of the CVD-addressing laser oscillator and the modification-addressing laser oscillator, and adapted to oscillate the beam of CVD-addressing laser light and the beam of modification-addressing laser light concurrently or individually.

According to one of the aspects, the CVD-addressing raw material gas may preferably be selected from among W(CO)₆, Cr(CO)₆, and Mo(CO)₆.

According to other aspects of this invention, there is given a wiring correcting method comprising: a CVD process including exposing a side of a correction-addressing substrate to a CVD-addressing raw material gas, and irradiating a beam of CVD-addressing laser light on the correction-addressing substrate, causing a photo-degradation of the CVD-addressing raw material gas to develop on a laser-irradiated surface of the correction-addressing substrate, having agglomerates of a correction-addressing metal selectively deposited on the laser-irradiated surface, thereby forming a length of correction-addressing metal wiring thereon; and a modification process including irradiating a beam of modification-addressing laser light having a different wavelength relative to the beam of CVD-addressing laser light on agglomerates of the correction-addressing metal, thereby melting agglomerates of the correction-addressing metal.

According to one of the other aspects for the wiring correcting method, the CVD process and the modification process may preferably be implemented concurrently.

According to one of the other aspects for the wiring correcting method, the beam of CVD-addressing laser light may preferably comprise ultraviolet laser light, and the beam of modification-addressing laser light may preferably comprise pulse-oscillated infrared laser light.

### Effects of Invention

According to the aspects of this invention, there can be implemented reduced resistances of pieces of correction-addressing metal wirings formed by employing a laser CVD method. According to one of the aspects, the wiring correcting device may well comprise an optical system operable to have the beam of CVD-addressing laser light and the beam of modification-addressing laser light irradiated at a region on the correction-addressing substrate, allowing for formation of a length of correction-addressing metal wiring with an even electric resistance.

According to one of the aspects, the wiring correcting device may well be configured to be set to have the beam of CVD-addressing laser light and the beam of modification-addressing laser light oscillated concurrently, thereby allowing for an efficient production of a length of correction-addressing metal wiring with a low resistance.

### BRIEF DESCRIPTION OF THE DRAWINGS

FIG. 1 is a configuration diagram of a wiring correcting device according to a first embodiment of this invention.

FIG. 2 is a sectional explanatory diagram of a correcting wire forming section (as a laser CVD device) constituting the wiring correcting device according to the first embodiment of this invention.

FIG. 3 is an explanatory diagram showing a process of forming a length of correction-addressing metal wiring by applying a first wiring correcting method using the wiring correcting device according to the first embodiment of this invention.

FIG. 4-1 is an explanatory diagram showing a process of forming a length of non-modified correction-addressing metal wiring by applying a second wiring correcting method using the wiring correcting device according to the first embodiment of this invention.

FIG. 4-2 is an explanatory diagram showing a process of melting and solidifying a length of non-modified correction-addressing metal wiring, to modify into a length of correction-addressing metal wiring, by applying the second wiring correcting method using the wiring correcting device according to the first embodiment of this invention.

FIG. 4-3 is an explanatory diagram showing a process of forming a length of correction-addressing metal wiring by applying the second wiring correcting method using the wiring correcting device according to the first embodiment of this invention.

FIG. 5 is a configuration diagram of a wiring correcting device according to a second embodiment of this invention.

### MODES OF EMBODIMENT FOR CARRYING OUT THE INVENTION

There will be described details of wiring correcting devices and wiring correcting methods according to embodiments of this invention, with reference being made to the drawings. It however is noted that the drawings are schematic, and involve members different from actual ones in, among others, their dimensions, dimensional proportions, shapes, or such. Further, between drawings, there are involved parts different from each other in, among others, their dimensional relations, proportions, or shapes.

### First Embodiment

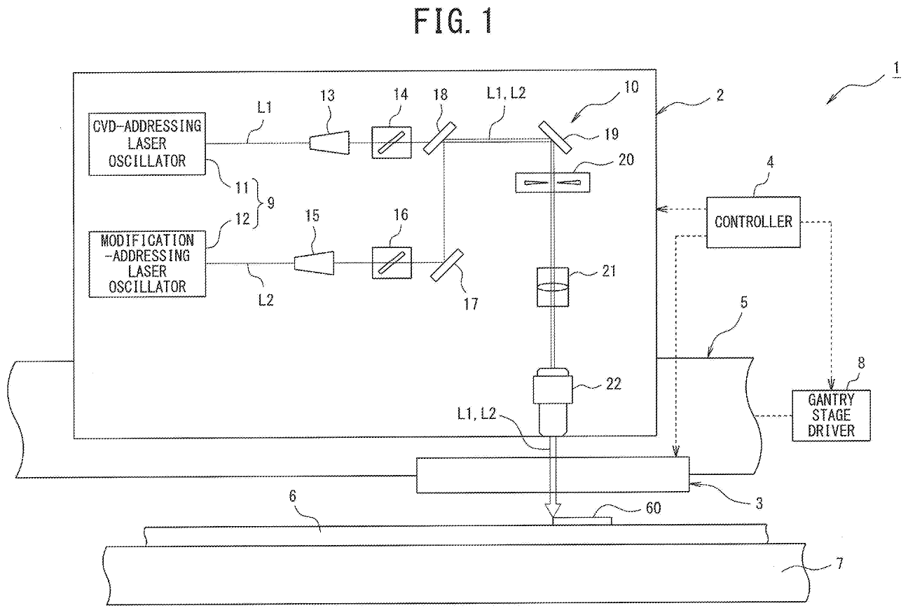

FIG. 1 shows a wiring correcting device 1 according to a first embodiment of this invention. The wiring correcting device 1 includes an optical system housing 2, a correcting wire forming section 3, and a controller 4. In the wiring correcting device 1 according to this embodiment, the optical system housing 2 and the correcting wire forming section 3 are mounted on a gantry stage 5 serving as a positioning mechanism.

The wiring correcting device 1 is configured to provide a series of wiring correction services over a correction-addressing substrate 6. As the correction-addressing substrate 6, there may well be applied, for instance, among others, a TFT substrate constituting a display device, such as a liquid crystal display or an organic EL display, a semiconductor substrate, or the like. In this embodiment, tungsten (W) is a correction-addressing metal. There is shown a length of correction-addressing metal wiring 60 made of tungsten, which is produced by a laser CVD method using the wiring correcting device 1.

The gantry stage 5 is installed on a non-depicted base. On the base, there is furnished a table 7 for the correction-addressing substrate 6 to be placed thereon. The gantry stage 5 is operable by a gantry stage driver 8, to displace the optical system housing 2 together with the correcting wire forming section 3 in non-depicted X-Y directions relative to the table 7. Namely, the optical system housing 2 and the correcting wire forming section 3 are movable relative to the correction-addressing substrate 6.

(Optical System Housing)

Description is now made of schematic configuration of the optical system housing 2, using FIG. 1. The optical system housing 2 is configured with a light source 9 and an optical system 10.

The light source 9 includes a pair of oscillators being a CVD-addressing laser oscillator 11 and a modification-addressing laser oscillator 12. In this embodiment, the CVD-addressing laser oscillator 11 and the modification-addressing laser oscillator 12 in the optical system housing 2 may well be driven concurrently. Or, the CVD-addressing laser oscillator 11 may well be driven to implement the laser CVD method, before using the modification-addressing laser oscillator 12 to implement a modification process.

The CVD-addressing laser oscillator 11 is configured to oscillate ultraviolet laser light as CVD-addressing laser light having a wavelength of 355 nm, for instance. The modification-addressing laser oscillator 12 is configured to pulse-oscillate infrared laser light as modification-addressing laser light having a wavelength of 1,064 nm, for instance, that is different in wavelength from the ultraviolet laser light. There is a combination of a beam L1 of CVD-addressing laser light oscillated at the CVD-addressing laser oscillator 11 and a beam L2 of modification-addressing laser light oscillated at the modification-addressing laser oscillator 12, which are shot in a direction. Note this invention is not restricted to the above-noted combination of laser light, so long as the combination to be involved is between a beam of laser light that can operate as CVD-addressing laser light and a beam of laser light that can operate as modification-addressing laser light. It also is noted that this invention employs a drive system to provide the beam of modification-addressing laser light. This drive system is not restricted to a pulse oscillation.

The ultraviolet laser light is sometimes referred to as THG (Third Harmonic Generation) laser light. In this embodiment, since the ultraviolet laser light is employed as CVD-addressing laser light, there can be suppressed thermal stresses acting on members of the correction-addressing substrate 6, allowing for a selective formation of a length of correction-addressing metal wiring 60 at a respective minute region on the correction-addressing substrate 6.

The infrared laser light is adapted to penetrate transparent substances, so it can be irradiated on surfaces of the correction-addressing substrate 6, without giving damages to a glass window portion 32 of the correcting wire forming section 3 that will be described later on. It is noted that the infrared laser light is sometimes referred to as IR (Infra-Red) laser light. The infrared laser light is pulse-oscillated, and thereby enabled to instantaneously melt agglomerates of correction-addressing metal in the modification process to be described later on.

As shown in FIG. 1, the optical system 10 includes a combination of a first beam expander 13 and a first attenuator 14, and a combination of a second beam expander 15 and a second attenuator 16. Further, it includes a combination of a first mirror 17, a wavelength selecting mirror 18, and a second mirror 19. In addition, it includes a combination of a slit 20, an infinity correction lens 21, and an objective lens 22.

The first beam expander 13 is configured to adequately expand a beam diameter of the CVD-addressing laser beam L1. The first attenuator 14 is configured to adequately adjust a power level of the CVD-addressing laser beam L1 having passed the first beam expander 13. The second beam expander 15 is configured to adequately expand a beam diameter of the modification-addressing laser beam L2. The second attenuator 16 is configured to adequately adjust a power level of the modification-addressing laser beam L2 having passed the second beam expander 15. The first mirror 17 is configured to reflect the modification-addressing laser beam L2 having passed the second attenuator 16.

The wavelength selecting mirror 18 is configured to pass the CVD-addressing laser beam L1, and reflect the modification-addressing laser beam L2 having been reflected at the first mirror 17, when the CVD-addressing laser oscillator 11 and the modification-addressing laser oscillator 12 are driven concurrently. The second mirror 19 is configured to reflect the CVD-addressing laser beam L1 and/or the modification-addressing laser beam L2 having routed the wavelength selecting mirror 18, toward the correcting wire forming section 3. The slit 20 is configured to adequately adjust a beam diameter of the CVD-addressing laser beam L1 and/or the modification-addressing laser beam L2 having routed the second mirror 19. The infinity correction lens 21 is configured to implement an infinity correction of the CVD-addressing laser beam L1 and/or the modification-addressing laser beam L2 having passed the slit 20. The objective lens 22 is configured to shoot the CVD-addressing laser beam L1 and/or the modification-addressing laser beam L2 to the correcting wire forming section 3 side.

It is noted that the objective lens 22 is adapted to finally determine (a) beam diameter(s) of the CVD-addressing laser beam L1 and/or the modification-addressing laser beam L2 at a surface of the correction-addressing substrate 6. The objective lens 22 may well be replaced by another objective lens having a different magnifying power depending on a width dimension of a wire to be formed on the surface of the correction-addressing substrate 6.

(Correcting Wire Forming Section)

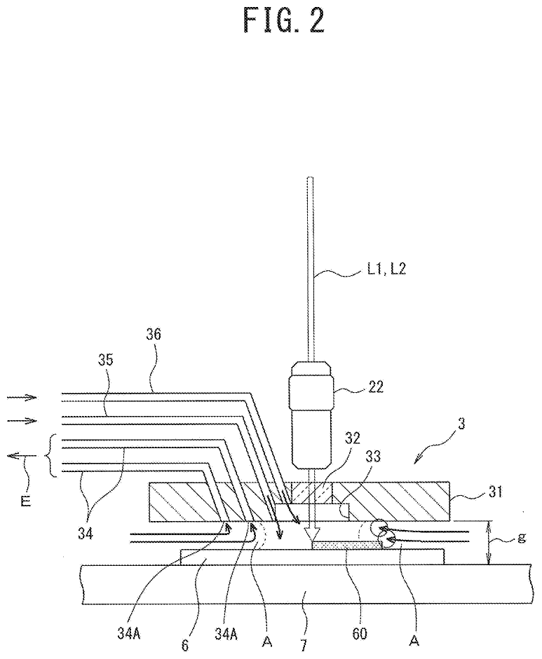

Description is now briefly made of configuration of the correcting wire forming section 3, inclusive of known configurations, with reference being made to FIG. 2. The correcting wire forming section 3 is configured as a laser CVD device to be a device adapted for use of the laser CVD method to form correction-addressing metal wirings 60, as they are made of tungsten (W) as a correction-addressing metal.

The correcting wire forming section 3 is configured with a platy forming section body 31, which has the glass window portion 32 provided at a central portion thereof. The forming section body 31 has a recess 33 formed at a downside of the glass window portion 32, to thereby define a volume of space for accumulating a CVD-addressing raw material gas. There is a set of air exhaust pipes 34 arranged to have their ends 34A opening at locations on a downside of the forming section body 31, surrounding the recess 33. The air exhaust pipes 34 are provided to exhaust streams of air in an arrowed direction E. In this embodiment, the air exhaust pipes 34 are disposed to have the ends thereof opening at the downside of the forming section body 31. It however is noted that there may be formed a channel extending to go around the recess 33, having a set of openings provided at a bottom of the channel, in combination with a single air exhaust pipe 34 arranged to communicate with the set of openings. As illustrated in FIG. 2, there are sets of layered air streams A produced in gaps surrounding the recess 33, between the correction-addressing substrate 6 and the forming section body 31, by sucking up air at openings of the above-noted ends 34A.

The space in the recess 33 of the forming section body 31 communicates with insides of a raw material gas supply pipe 35 provided to supply a CVD-addressing raw material gas, and a purge gas supply pipe 36 provided to supply a purge gas. As the CVD-addressing raw material gas, there is used tungsten carbonyl (W(CO)₆). In this correcting wire forming section 3, there are sets of layered streams produced by sucking air at the ends 34A of the air exhaust pipes 34, thus having a volume of space enclosed by such sets of layered streams of air A surrounding the recess 33 from around, which permits the CVD-addressing raw material gas to be supplied only to a minute space below the glass window portion 32. This configuration eliminates the need for using a CVD-addressing chamber large in size, even when the correction-addressing substrate 6 is large in size.

As shown in FIG. 2, the glass window portion 32 of the correcting wire forming section 3 is disposed to position beneath the objective lens 22 of the optical system housing 2. As will be seen from FIG. 1, the correcting wire forming section 3 is arranged together with the optical system housing 2 on the gantry stage 5, keeping such positional relationships.

(First Wiring Correcting Method: Including Concurrently Driving the CVD-Addressing Laser Oscillator and the Modification-Addressing Laser Oscillator)

Description is now made of a first wiring correcting method using the wiring correcting device 1 according to the embodiment, as well as operations and effects thereof.

First, as shown in FIG. 1, the correction-addressing substrate 6 is set in place on the table 7. Then, the controller 4 is operated for controlling the gantry stage driver 8 in accordance with a set of data on locations of wiring defects, so the gantry stage 5 is moved to have the glass window portion 32 of the correcting wire forming section 3 placed in a corresponding position above a location constituting a start point of a length of correction-addressing metal wiring 60 to be formed on the correction-addressing substrate 6.

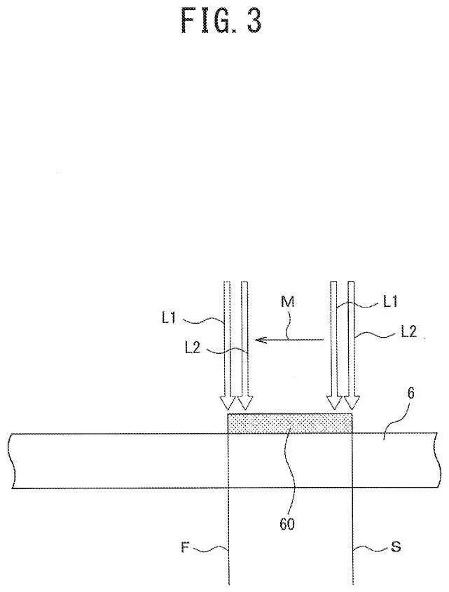

Next, the controller 4 is operated for controlling the CVD-addressing laser oscillator 11 and the modification-addressing laser oscillator 12, to concurrently oscillate a CVD-addressing laser beam L1 and a modification-addressing laser beam L2. The CVD-addressing laser beam L1 and the modification-addressing laser beam L2 are directed by the wavelength selecting mirror 18, to go along an optical path, constituting a mixed beam. This beam is reflected by the second mirror 19, to go downward, passing the slit 20, the infinity correction lens 21, the objective lens 22, and the glass window portion 32 of the correcting wire forming section 3, to irradiate the location constituting the start point (designated by a sign S in FIG. 3) of the length of correction-addressing metal wiring 60 to be formed on the correction-addressing substrate 6.

At this time, there is performed a combination of air exhausting control for the air exhaust pipes 34 and gas introducing control for the raw material gas supply pipe 35 and the purge gas supply pipe 36 of the correcting wire forming section 3. Under this condition, the correcting wire forming section 3 is displaced together with the optical system housing 2, so the mixed beam has a position thereof on the correction-addressing substrate 6 displaced to a location corresponding to a final point (designated by a sign F in FIG. 3) as an end of the length of correction-addressing metal wiring 60 to be formed on the correction-addressing substrate 6. Along with this, there can be deposited agglomerates of tungsten constituting the length of correction-addressing metal wiring 60. In other words, as shown in FIG. 2, the CVD-addressing raw material gas is always supplied within a vicinity of the recess 33 the correcting wire forming section 3 has at the downside of the forming section body 31, thus permitting a length of correction-addressing metal wiring 60 to be produced along a track of displacement of the mixed beam.

According to this embodiment, the wiring correcting device 1 is operable to concurrently supply a CVD-addressing laser beam L1 and a modification-addressing laser beam L2 through the objective lens 22 to the correction-addressing substrate 6, thus permitting agglomerates of tungsten deposited on the correction-addressing substrate 6 to be melted instantaneously by the modification-addressing laser beam L2. FIG. 3 shows a mixed beam as a combination of a CVD-addressing laser beam L1 and a modification-addressing laser beam L2 concurrently supplied to a start point S of a length of correction-addressing metal wiring 60 on the correction-addressing substrate 6, and displaced therefrom to move in a sense represented by an arrow M. According to this wiring correcting method, the modification-addressing laser beam L2 can have a track of displacement thereof coincident with that of the CVD-addressing laser beam L1. Further, according to this wiring correcting method, there can be a combination of a CVD process and a modification process implemented concurrently, thus allowing for a correction needing a reduced time.

According to this embodiment, the wiring correcting device 1 is adapted to have a length of correction-addressing metal wiring 60 produced on the correction-addressing substrate 6, with a crystal structure densified by passing a melting using a modification-addressing laser beam L2. Accordingly, the wiring correcting device 1 is adapted to provide pieces of correction-addressing metal wiring 60 with reduced resistances.

According to this embodiment, the wiring correcting device 1 configured as described is adapted for use of the optical system 10 to have a mixed beam as a combination of a beam of CVD-addressing laser light and a beam of modification-addressing laser light irradiated to a region on a correction-addressing substrate 6. Accordingly, there can be an ensured modification treatment to be implemented without misalignments between a set of CVD-processed positions and a set of quality-modified positions, simply by moving the gantry stage 5 provided with the optical system housing 2 and the correcting wire forming section 3.

(Second Wiring Correcting Method: Including Individually Driving the CVD-Addressing Laser Oscillator and the Modification-Addressing Laser Oscillator)

Also there is implemented a second wiring correcting method that includes independently driving the CVD-addressing laser oscillator 11 for employing a CVD method to deposit a set of agglomerates of tungsten, followed by independently driving the modification-addressing laser oscillator 12 for modifying a quality of the set of agglomerates of tungsten.

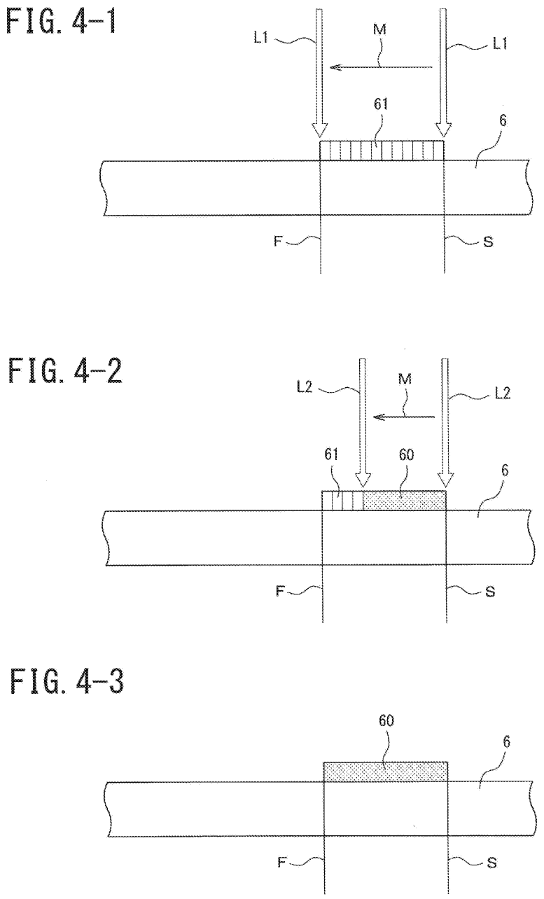

For the second wiring correcting method, there is given a series of process charts illustrated in FIGS. 4-1 through 4-3. As illustrated in FIG. 4-1, in the second wiring correcting method, there is made an irradiation or a sequence of shots of a CVD-addressing laser beam L1 only, as it is irradiated or sequentially shot, describing a track from a position constituting a start point (denoted by S) to a position constituting a final point (denoted by F). Along this track, there is formed a length of correction-addressing non-modified metal wiring 61.

Next, as illustrated in FIG. 4-2, there is made an irradiation or a sequence of shots of a modification-addressing laser beam L2 only, as it is displaced along the above-noted track to shoot on an involved part of the length of correction-addressing non-modified metal wiring 61, to make this part once melted to re-solidify with a densified crystal structure. By doing so, as illustrated in FIG. 4-3, there can be produced a length of correction-addressing metal wiring 60 made of dense tissues of tungsten with reduced resistances.

Such the second wiring correcting method may well repeat a CVD process to have a stacked layer of correction-addressing non-modified metal wiring 61, allowing for a wiring height to be secured before entering a modification process. Further, the second wiring correcting method may well have a beam of modification-addressing laser light irradiated a plurality of times on a length of correction-addressing non-modified metal wiring 61. In this case, the length of correction-addressing non-modified metal wiring 61 composed of a set of deposited agglomerates of particulate tungsten can be melted to re-solidify in an ensured manner, thus permitting a length of correction-addressing metal wiring 60 to be bulked, allowing for a wide reduced wiring resistance value.

### Second Embodiment

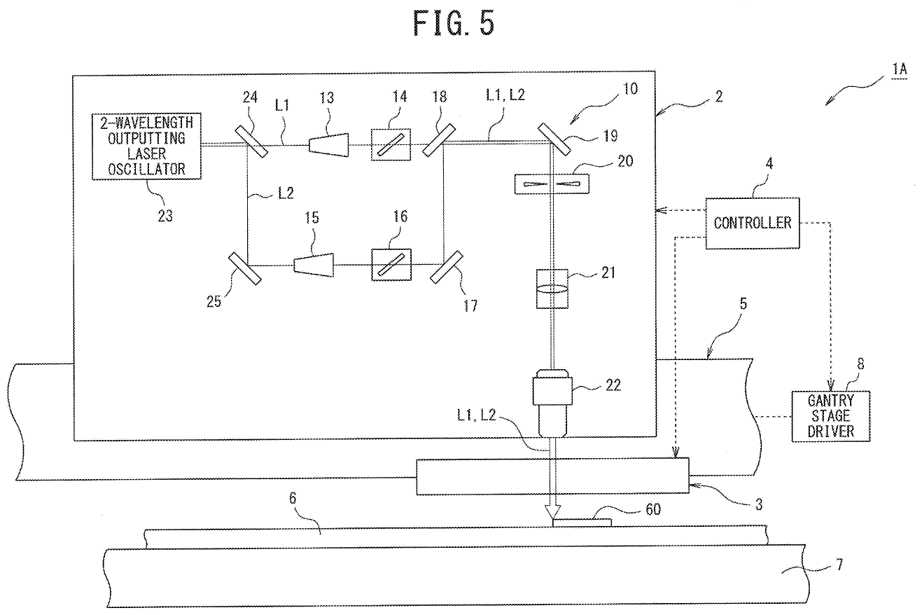

FIG. 5 shows a wiring correcting device 1A according to a second embodiment of this invention. This wiring correcting device 1A has a configuration mainly different from the wiring correcting device 1 according to the first embodiment, in that the former has a 2-wavelength outputting laser oscillator 23 serving as a combination of the CVD-addressing laser oscillator and the modification-addressing laser oscillator. The 2-wavelength outputting laser oscillator 23 may well comprise a laser device employed and adapted to oscillate a beam of CVD-addressing laser light and a beam of modification-addressing laser light concurrently or individually. In this embodiment as well, the beam of CVD-addressing laser light to be employed may well be ultraviolet laser light, and the beam of modification-addressing laser light to be employed may well be infrared laser light.

As shown in FIG. 5, the wiring correcting device 1A includes a combination of: a wavelength selecting mirror 24 configured to pass a CVD-addressing laser beam L1 output from the 2-wavelength outputting laser oscillator 23, and reflect a modification-addressing laser beam L2 output from the 2-wavelength outputting laser oscillator 23; and a third mirror 25 configured to reflect the modification-addressing laser beam L2 having been reflected at the wavelength selecting mirror 24, so that this laser beam L2 takes an optical path extending in parallel with the CVD-addressing laser beam L1. The wiring correcting device 1A according to this embodiment has other components than described, which are identical to those of the wiring correcting device 1 according to the first embodiment, and their description is omitted to avoid redundancy. It is noted that also the wiring correcting device 1A according to this embodiment is applicable to the first wiring correcting method that employs a combination of a CVD-addressing laser beam L1 and a modification-addressing laser beam L2 oscillated concurrently, and to the second wiring correcting method that implements a CVD process before implementing a modification process.

According to the second embodiment described, the wiring correcting device 1A employing the 2-wavelength outputting laser oscillator 23 can be down-sized. In particular, the second embodiment employing the 2-wavelength outputting laser oscillator 23 permits an optical system housing 2 thereof to be down-scaled and light-weighted, allowing for smoothed displacements of the optical system housing 2 relative to a gantry stage 5.

### OTHER EMBODIMENTS

Although there have been described embodiments of this invention as well as examples thereof, involved drawings or phrases constituting partial disclosure of such embodiments or examples should not be construed as restrictions to this invention. Artisan may have various embodiments, examples, or operational techniques as substitutes turned apparent from the foregoing disclosure.

For instance, there may well be employed chromium (Cr) or molybdenum (Mo) as a substitute for tungsten (W) that has been employed as a correction-addressing metal in the foregoing embodiments. In this case, as a CVD-addressing raw material gas, chromium carbonyl (Cr(CO)₆) or molybdenum carbonyl (Mo(CO)₆) is to be used. It however is noted that in this invention the correction-addressing metal to be applied is not limited to tungsten (W), chromium (Cr), or molybdenum (Mo), and may well be other metal.

In the foregoing embodiments, the gantry stage 5 has been driven to move the optical system housing 2 and the correcting wire forming section 3 in X-Y directions. However, there may well be arrangements including a section constituting an end of a correction-addressing substrate 6 and configured to move in X-Y directions.

In the foregoing embodiments, there has been ultraviolet laser light employed as CVD-addressing laser light. It is noted that there may well be FHG (Fourth Harmonic Generation) laser light employed instead thereof. Further, in the foregoing embodiments, there has been infrared laser light employed as modification-addressing laser light. It is noted that there may well be SHG (Second Harmonic Generation) laser light employed instead thereof. It however is noted that in this invention the beam of CVD-addressing laser light to be employed is not limited to ultraviolet laser light or FHG laser light, and may well be other laser light. It also is noted that in this invention the beam of modification-addressing laser light to be employed is not limited to infrared laser light or SHG laser light, and may well be other laser light.

It also is noted that according to this invention each of the wiring correcting devices 1 and 1A in the embodiments described may well be configured for use of the beam of modification-addressing laser light to modify a quality of an existing wiring.

### DESCRIPTION OF REFERENCE SIGNS

1, 1A wiring correcting device
2 optical system housing
5 gantry stage
6 correction-addressing substrate
8 gantry stage driver
9 light source
10 optical system
11 CVD-addressing laser oscillator
12 modification-addressing laser oscillator
23 2-wavelength outputting laser oscillator
60 correction-addressing metal wiring
L1 CVD-addressing laser beam
L2 modification-addressing laser beam

1. A wiring correcting device configured to have a beam of CVD-addressing laser light oscillated at a CVD-addressing laser oscillator and irradiated on a correction-addressing substrate exposed to a CVD-addressing raw material gas at a side thereof, causing a photo-degradation of the CVD-addressing raw material gas to develop on a laser-irradiated surface of the correction-addressing substrate, having agglomerates of a correction-addressing metal selectively deposited on the laser-irradiated surface, to thereby form a length of correction-addressing metal wiring thereon, wherein
the wiring correcting device comprises a modification-addressing laser oscillator, and
the modification-addressing laser oscillator is configured to oscillate a beam of modification-addressing laser light having a different wavelength relative to the beam of CVD-addressing laser light, and adapted to melt agglomerates of the correction-addressing metal.

2. The wiring correcting device as claimed in claim 1, wherein the wiring correcting device comprises an optical system operable to have the beam of CVD-addressing laser light and the beam of modification-addressing laser light irradiated at a region on the correction-addressing substrate.

3. The wiring correcting device as claimed in claim 1, wherein the wiring correcting device is configured to be set to have the beam of CVD-addressing laser light and the beam of modification-addressing laser light oscillated concurrently.

4. The wiring correcting device as claimed in claim 1, wherein the wiring correcting device is configured to be set to irradiate the beam of CVD-addressing laser light to form the length of correction-addressing metal wiring, before irradiating the beam of modification-addressing laser light on a length of correction-addressing metal wiring.

5. The wiring correcting device as claimed in claim 1, wherein the beam of CVD-addressing laser light comprises ultraviolet laser light, and the beam of modification-addressing laser light comprises pulse-oscillated infrared laser light.

6. The wiring correcting device as claimed in claim 1, wherein the wiring correcting device comprises a 2-wavelength outputting laser oscillator serving as a combination of the CVD-addressing laser oscillator and the modification-addressing laser oscillator, and adapted to oscillate the beam of CVD-addressing laser light and the beam of modification-addressing laser light concurrently or individually.

7. The wiring correcting device as claimed in claim 1, wherein the CVD-addressing raw material gas is selected from among W(CO)₆, Cr(CO)₆, and Mo(CO)₆.

8. A wiring correcting method comprising:
a CVD process including exposing a side of a correction-addressing substrate to a CVD-addressing raw material gas, and irradiating a beam of CVD-addressing laser light on the correction-addressing substrate, causing a photo-degradation of the CVD-addressing raw material gas to develop on a laser-irradiated surface of the correction-addressing substrate, having agglomerates of a correction-addressing metal selectively deposited on the laser-irradiated surface, thereby forming a length of correction-addressing metal wiring thereon; and
a modification process including irradiating a beam of modification-addressing laser light having a different wavelength relative to the beam of CVD-addressing laser light on agglomerates of the correction-addressing metal, thereby melting agglomerates of the correction-addressing metal.

9. The wiring correcting method as claimed in claim 8, wherein the CVD process and the modification process are implemented concurrently.

10. The wiring correcting method as claimed in claim 8, wherein the beam of CVD-addressing laser light comprises ultraviolet laser light, and the beam of modification-addressing laser light comprises infrared laser light.
